(19) United States
(12) Patent Application Publication
(10) Pub. No.: US 2016/0133824 A1
(43) Pub. Date: May 12, 2016

(54) ACTUATOR

(71) Applicant: Murata Manufacturing Co., Ltd., Nagaokakyo-shi (JP)

(72) Inventors: Kenji Kagayama, Nagaokakyo-shi (JP); Toshio Imanishi, Nagaokakyo-shi (JP); Hiroaki Kaida, Nagaokakyo-shi (JP)

(21) Appl. No.: 14/988,053

(22) Filed: Jan. 5, 2016

Related U.S. Application Data
(63) Continuation of application No. PCT/JP2014/067641, filed on Jul. 2, 2014.

(30) Foreign Application Priority Data
Jul. 8, 2013 (JP) 2013-142252

(51) Int. Cl. H01L 41/09

(52) U.S. Cl. CPC H01L 41/092; H01L 41/0926

(57) ABSTRACT

An actuator that includes a plate-like elastic member. When seen from a first principal surface side in a plan view, the plate-like elastic member has a shape in which the elastic member extends along a circular arc-shaped center line. The plate-like elastic member is torsionally displaced relative to the circular arc-shaped center line as a central axis.

### CROSS REFERENCE TO RELATED APPLICATIONS

The present application is a continuation of International application No. PCT/JP2014/067641, filed Jul. 2, 2014, which claims priority to Japanese Patent Application No. 2013-142252, filed Jul. 8, 2013, the entire contents of each of which are incorporated herein by reference.

### FIELD OF THE INVENTION

The present invention relates to an actuator for driving various components and members, and particularly relates to an actuator which is displaced in torsional behavior.

### BACKGROUND OF THE INVENTION

Hitherto, actuators have been widely used for moving various components and members or for changing the directions of various members and components. Patent Document 1 described below discloses an actuator using a piezoelectric element having a bimorph structure. In the actuator, two piezoelectric ceramic plates are attached together. The one piezoelectric ceramic plate and the other piezoelectric ceramic plate are displaced in opposite directions. The actuator bends. Therefore, when one end of the actuator is fixed, the other end side of the actuator is displaced.

Patent Document 1: Japanese Unexamined Patent Application Publication (Translation of PCT Application) No. 2005-518287

### SUMMARY OF THE INVENTION

In recent years, for an actuator, a further increase in a displacement amount thereof is desired.

An object of the present invention is to provide an actuator which allows a displacement enlargement ratio to be increased.

An actuator according to an aspect of the present invention includes a plate-like elastic member and a driving member configured to displace the plate-like elastic member.

In an aspect of the present invention, the plate-like elastic member has a first principal surface and a second principal surface at a side opposite to the first principal surface.

In another aspect of the present invention, the elastic member has a shape in which the elastic member extends along a circular arc-shaped center line, when seen from the first principal surface side in a plan view, and the elastic member is constructed to be torsionally displaced relative to the circular arc-shaped center line as a central axis.

In a specific aspect of the actuator according to the present invention, the elastic member includes a plurality of elastic plates disposed so as to extend along a direction in which the circular arc-shaped center line extends, and the plurality of elastic plates are connected to each other to form the elastic member.

In another specific aspect of the actuator according to the present invention, the adjacent elastic plates of the plurality of elastic plates are connected to each other via a connection member.

In still another specific aspect of the actuator according to the present invention, the plurality of elastic plates are connected directly to each other.

In still another specific aspect of the actuator according to the present invention, the circular arc-shaped center line has a central angle of 360°.

In still another specific aspect of the actuator according to the present invention, the elastic plate has a length direction, and the adjacent elastic plates are connected to each other so as to form a certain angle when being seen in a plan view.

In still another specific aspect of the actuator according to the present invention, the connection members are alternately disposed at an outer peripheral side or an inner peripheral side in a direction in which the circular arc-shaped center line extends.

In still another specific aspect of the actuator according to the present invention, the elastic plate includes a piezoelectric element including a piezoelectric plate and an electrode formed on the piezoelectric plate.

In still another specific aspect of the actuator according to the present invention, the elastic plate includes a plurality of piezoelectric elements configured to vibrate in a bending mode, and the plurality of piezoelectric elements are connected to each other so as to form a meander shape when being seen in a plan view.

In the actuator according to the present invention, since the plate-like elastic member has the above-described shape and deforms in torsional behavior, it is possible to increase a displacement enlargement ratio.

### BRIEF DESCRIPTION OF THE DRAWINGS

FIG. 1 is a perspective view for explaining an actuator according to a first embodiment of the present invention.

FIGS. 2(a) and 2(b) are a perspective view for explaining torsional behavior of the actuator of the first embodiment and an end view for explaining a displacement state as seen from one end portion of the actuator.

FIG. 3 is a diagram showing the central angle of a circular arc and a displacement amount in the actuator of the first embodiment.

FIG. 4 is a schematic plan view for explaining respective parameters in the actuator of the first embodiment which are used to obtain the results shown in FIG. 3.

FIG. 5 is a perspective view showing one elastic plate used in the actuator of the first embodiment.

FIG. 6 is a perspective view showing a piezoelectric element in the elastic plate shown in FIG. 5.

FIG. 7 is a cross-sectional view for explaining bending behavior of the piezoelectric element shown in FIG. 6.

FIG. 8 is a cross-sectional view for explaining bending behavior of a piezoelectric element of a modification.

FIG. 9 is a cross-sectional view showing bending behavior of a piezoelectric element according to still another modification.

FIG. 10 is a schematic perspective view for explaining deformation by torsional behavior of the elastic plate shown in FIG. 5.

FIG. 11 is a perspective view for explaining an actuator according to a second embodiment of the present invention.

FIG. 12 is a perspective view for explaining displacement behavior of the actuator of the second embodiment shown in FIG. 11.

FIG. 13 is a perspective view showing a schematic structure of an actuator according to a third embodiment of the present invention.

FIG. 14 is a perspective view of an actuator according to a fourth embodiment of the present invention.

FIG. 15 is a perspective view showing a first modification of an actuator element used in an actuator of the present invention.

FIG. 16 is a perspective view showing deformation behavior of the actuator element shown in FIG. 15.

FIG. 17 is a perspective view showing a second modification of the actuator element used in the actuator of the present invention.

FIGS. 18(a) and 18(b) are a perspective view of an actuator according to a fifth embodiment of the present invention and a schematic end view for explaining deformation behavior at an end surface of the actuator.

FIG. 19 is a perspective view showing deformation behavior of an actuator of a comparative example.

FIG. 20 is a diagram showing a relationship between a displacement amount and the length of each of elements of the actuators of the fifth embodiment shown in FIGS. 18(a) and 18(b) and of the comparative example shown in FIG. 19.

FIG. 21 is a schematic plan view for explaining respective parameters in the actuator of the embodiment which are used to obtain the results shown in FIG. 20.

### DETAILED DESCRIPTION OF THE PREFERRED EMBODIMENTS

Hereinafter, the present invention will be clarified through description of specific embodiments of the present invention with reference to the drawings.

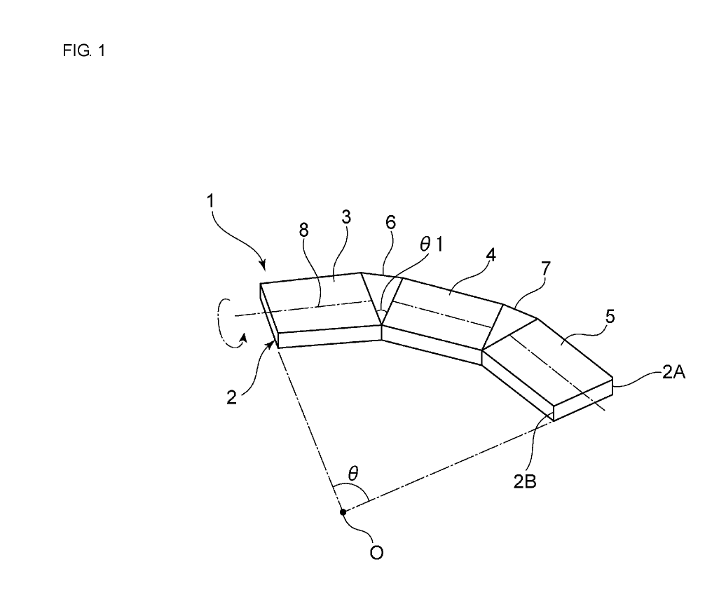

FIG. 1 is a perspective view for explaining an actuator according to a first embodiment of the present invention.

The actuator 1 of the present embodiment includes a plate-like elastic member 2. In the present embodiment, the elastic member 2 includes a plurality of elastic plates 3 to 5 and connection members 6 and 7. The elastic plate 3 and the elastic plate 4 are connected to each other via the connection member 6. The elastic plate 4 and the elastic plate 5 are connected to each other via the connection member 7. The upper surfaces of the plurality of elastic plates 3 to 5 are flush with the upper surfaces of the connection members 6 and 7, so that a first principal surface of the elastic member 2 is formed. The lower surfaces of the elastic plates 3 to 5 are flush with the lower surfaces of the connection members 6 and 7. A second principal surface of the elastic member 2 is formed by the lower surfaces of the elastic plates 3 to 5 and the lower surfaces of the connection members 6 and 7.

Each of the elastic plates 3 to 5 is driven by a piezoelectric element described later to deform in torsional behavior. The elastic plates 3 to 5 will be described in detail later. In the elastic member 2, the elastic plates 3 to 5 each have a rectangular plate-like shape. When seen in a plan view, the connection members 6 and 7 each form an isosceles triangle having a vertex angle of θ1. The plurality of elastic plates 3 to 5 are joined to each other via the connection members 6 and 7 such that the vertex angles θ1 of the isosceles triangles of the connection members 6 and 7 are at the same side.

Therefore, when the elastic member 2 is seen from the first principal surface side in a plan view, an outer first lateral surface 2A and an inner second lateral surface 2B each have a circular arc shape. The circular arc shape of the first lateral surface 2A when being seen in a plan view is referred to as a first circular arc, and the circular arc shape of the second lateral surface 2B when being seen in a plan view is referred to as a second circular arc. The center of the first and second circular arcs is O, and the central angle thereof is θ. That is, the planar shape of the elastic member 2 corresponds to a shape obtained by removing a sector shape defined by the second circular arc and having the central angle θ from a sector shape defined by the first circular arc and having the central angle θ.

In the actuator 1 of the present embodiment, the elastic member 2 is configured to deform in torsional behavior with a circular arc-shaped center line 8 as a central axis. The circular arc-shaped center line 8 has a circular arc shape having a center at the center O and passing through a center between the first circular arc and the second circular arc. As shown by an alternate long and short dashed line in FIG. 1, the circular arc-shaped center line 8 is a circular arc passing near the center of each of the elastic plates 3, 4, and 5 in the width direction thereof.

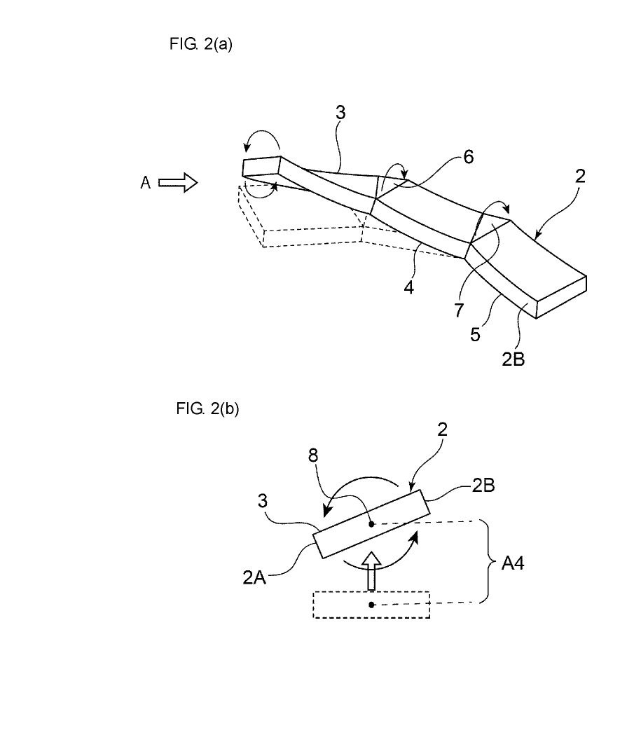

The connection members 6 and 7 are composed of elastic members made of ceramics, metal, or the like. On the other hand, the elastic plates 3 to 5 are composed of piezoelectric actuator elements described later. The elastic plates 3 to 5 each deform in a torsional mode as shown in FIG. 2(a). In this case, since the plurality of elastic plates 3 to 5 each deform in the torsional behavior as shown in FIG. 2(a), in the entire actuator 1, when one end side is fixed, a displacement amount at the other side is increased. FIG. 2(b) is an end view showing a displacement state of the elastic member 2 at an end portion thereof as seen from an arrow A side in FIG. 2(a).

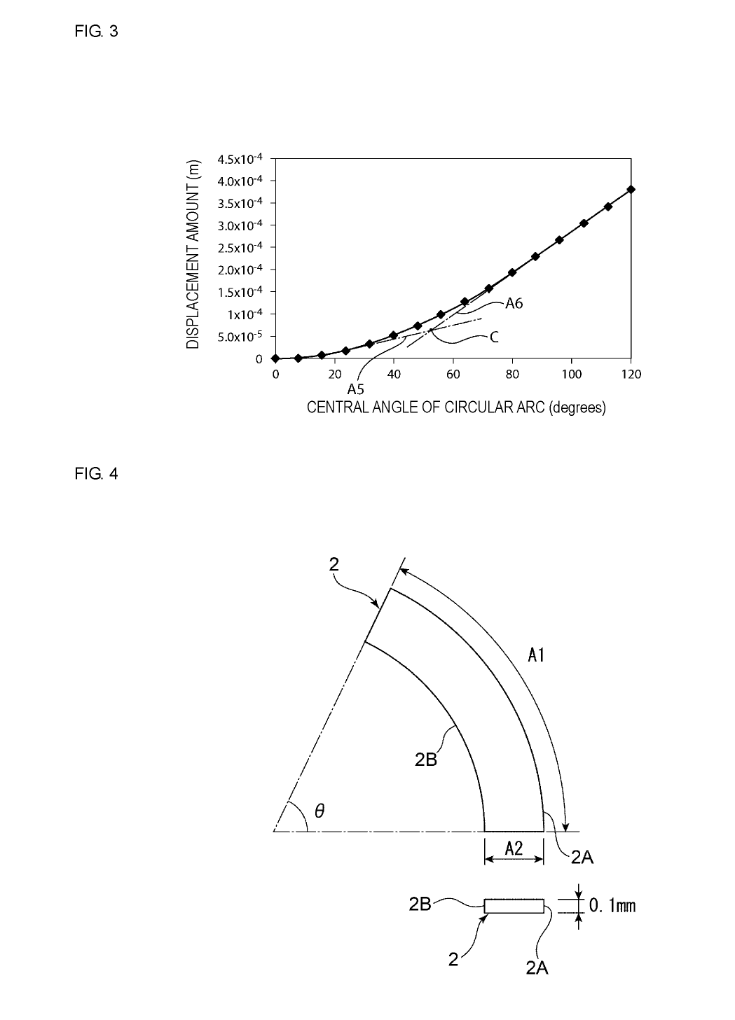

As described above, when seen in a plan view, the elastic member 2 has the substantially circular arc-shaped second lateral surfaces 2A and 2B, and takes torsional behavior with the circular arc-shaped center line 8 as a central axis. Thus, in the actuator 1 of the present embodiment, when one end side is fixed, it is possible to greatly increase displacement at the other end side. This will be described with reference to FIGS. 3 and 4.

FIG. 3 is a diagram showing a relationship between a displacement amount and the central angle θ in the actuator 1. The results in FIG. 3 are results obtained when the actuator 1 has dimensions A1 and A2 and a central angle θ shown in FIG. 4. Here, A1 which is the length of the first circular arc is set at 10 mm, the dimension A2 of the actuator 1 in the width direction is set at 2 mm, and the thickness thereof is set at 0.1 mm. In addition, the central angle θ is changed. When the actuator 1 is driven, a torsional angle is set at 1.5°/mm. That is, the actuator 1 including the elastic plates 3 to 5 is configured such that the entire elastic member 2 is twisted at 15°.

The displacement amount on the vertical axis in FIG. 3 refers to a maximum displacement amount at the other end side when one end side of the elastic member 2 is fixed. The maximum displacement amount refers to a displacement amount A4 in the vertical direction of the center line 8 in FIG. 2(b).

As is obvious from FIG. 3, it appears that the displacement amount increases as the central angle θ increases. This is because the displacement cumulative effect in the substantially circular arc-shaped elastic member 2 increases as the central angle θ increases. In particular, it appears that at a central angle equal to or greater than the angle at an inflection point C which is an intersection point between alternate long and short dashed lines AS and A6 in FIG. 3, the displacement amount relatively increases as the central angle θ increases. Therefore, θ is desirably equal to or greater than 50° which is the angle at the inflection point C.

As described above, in the actuator 1 including the circular arc-shaped elastic member 2, it appears that, when one end side is fixed, a great displacement amount is obtained if torsional behavior is utilized. It is possible to achieve such torsional behavior by forming the elastic plates 3 to 5 from actuator elements which are displaced in various torsional modes.

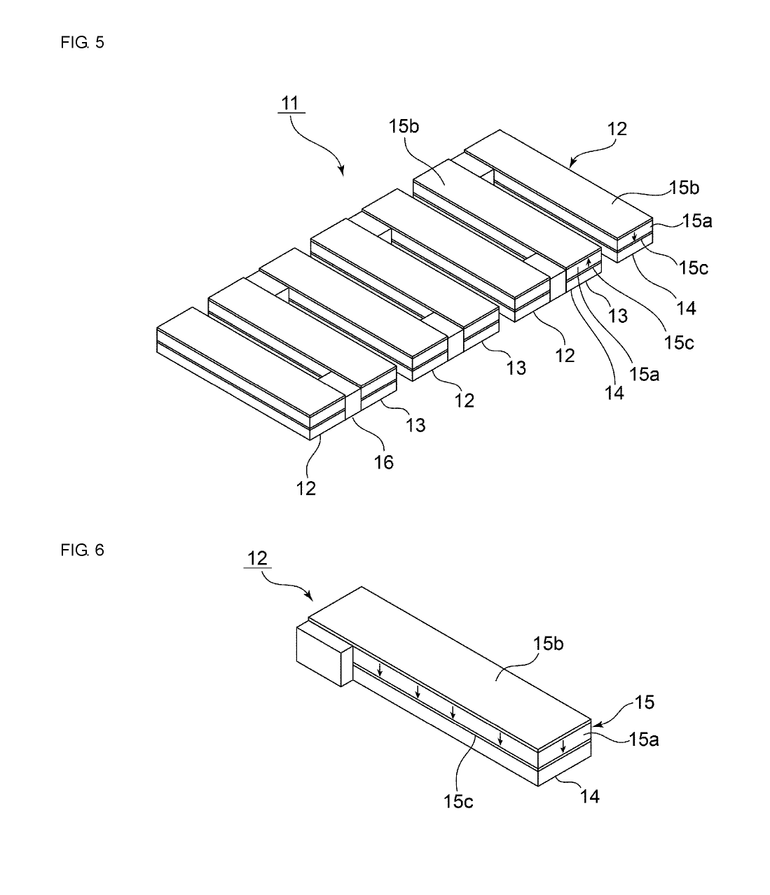

FIG. 5 is a perspective view showing an example of the actuator element forming the above-described elastic plate 3. An actuator element 11 has a structure in which piezoelectric actuator units 12 and piezoelectric actuator units 13 are alternately connected to each other via connection members 16. The connection members 16 are alternately disposed at one end side and the other end side in a direction in which the piezoelectric actuator units 12 and 13 are arranged. Therefore, the connection members 16 are alternately disposed at the outer peripheral side and the inner peripheral side in a direction in which the circular arc-shaped center line 8 of the actuator 1 extends.

As shown in FIG. 6, each piezoelectric actuator unit 12 has a structure in which a piezoelectric element 15 is laminated on an elastic plate 14. The elastic plate 14 may be formed from metal, ceramics, Si, or the like. The piezoelectric element 15 includes a piezoelectric ceramic plate 15a which is subjected to poling in a thickness direction as shown by arrows. Electrodes 15b and 15c are laminated on the upper surface and the lower surface of the piezoelectric ceramic plate 15a. The piezoelectric ceramic plate 15a is subjected to poling in the thickness direction.

The piezoelectric ceramic plate 15a may be formed from appropriate piezoelectric ceramics such as PZT. The electrodes 15b and 15c each may be formed from appropriate metal such as Ni, Au, Ag, Cu or an alloy thereof. Each connection member 16 is formed of an elastic member made of ceramics, metal, or the like.

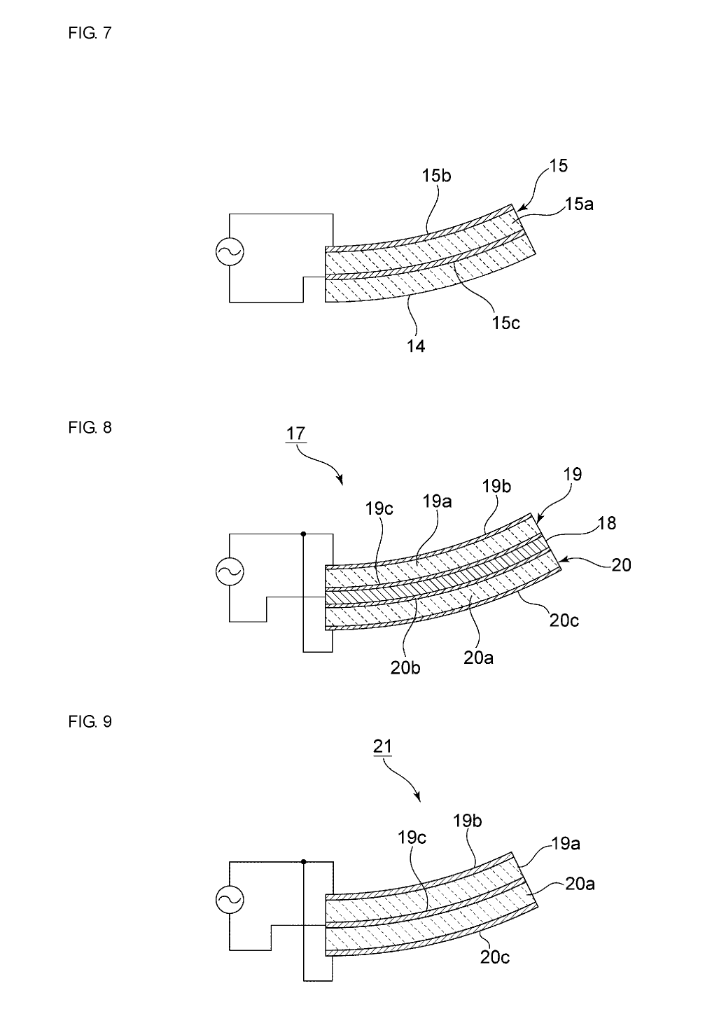

When a voltage is applied to the piezoelectric element 15 as shown in FIG. 7, the piezoelectric element 15 deforms in a bending mode.

Referring back to FIG. 5, each piezoelectric actuator unit 13 is configured similarly to each piezoelectric actuator unit 12, except that the polarization direction of the piezoelectric ceramic plate 15a is the opposite direction. Therefore, the electrode 15b of the piezoelectric actuator unit 12 and the electrode 15b of the piezoelectric actuator unit 13 are connected in common to be connected to the potential at one side, and the electrodes 15c at the lower side thereof are connected in common to be connected to the potential at the other side. As a result, the piezoelectric actuator unit 12 and the piezoelectric actuator unit 13 bend in opposite directions.

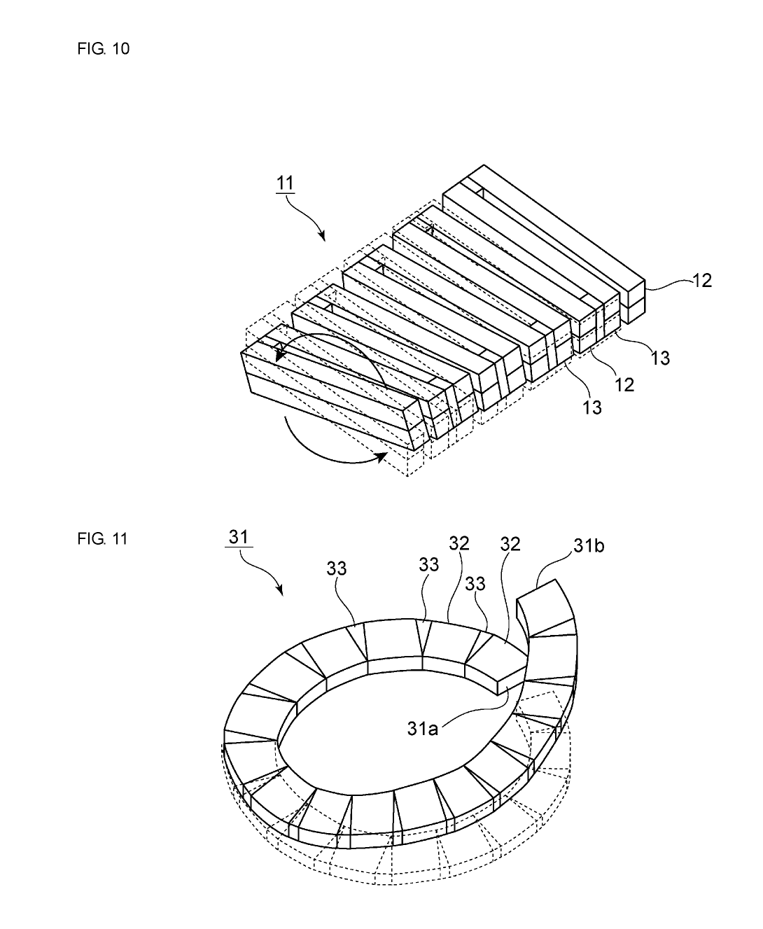

FIG. 10 is a schematic perspective view showing torsional behavior of the above-described actuator element 11. As is obvious from FIG. 10, when the piezoelectric actuator units 12 and 13 are driven, the piezoelectric actuator units 12 and 13 deform in torsional behavior from a state shown by a broken line in the drawing to a state shown by a solid line. That is, it is possible to achieve deformation behavior of the elastic plate 3 in FIG. 1. Thus, the entire actuator element 11 torsionally deforms.

As described above, it is possible to form the elastic plate 3 according to the first embodiment from the above-described actuator element 11. It is also possible to form each of other elastic plates 4 and 5 from the actuator element 11.

Instead of each of the above-described piezoelectric actuator units 12 and 13, a piezoelectric actuator unit 17 having a bimorph structure shown in FIG. 8 may be used. In the piezoelectric actuator unit 17, piezoelectric elements 19 and 20 are laminated on both surfaces of an elastic plate 18. The piezoelectric elements 19 and 20 include piezoelectric ceramic plates 19a and 20a and electrodes 19b, 19c, 20b, and 20c, respectively. Polarization directions in the piezoelectric elements 19 and 20 are made the same. As shown in the drawing, voltages having opposite polarity are applied to the piezoelectric elements 19 and 20. In this manner, it is possible to displace the piezoelectric actuator unit 17 having the bimorph structure in a bending manner.

In addition, as in a piezoelectric actuator unit 21 shown in FIG. 9, the elastic plate 18 may be removed from the above-described piezoelectric actuator unit 17.

With the actuator 1 of the present embodiment, it is possible to obtain a great displacement amount by deforming the elastic member 2 in torsional behavior. In this case, a driving member which drives the elastic member 2 in torsional behavior is the piezoelectric element 15 integrated with the elastic member 2.

In the present invention, the driving member which drives the elastic plate may be integrated with the elastic member, or may be configured as a member separate from the elastic member.

FIG. 11 is a perspective view for explaining an actuator according to a second embodiment of the present invention. In the actuator 31 of the second embodiment, an elastic member has a structure in which a plurality of elastic plates 32 are connected to each other via connection members 33. Each elastic plate 32 may be formed similarly to the elastic plate 3 of the first embodiment. The connection members 33 are also the same as the connection members 6 and 7 of the first embodiment.

The actuator 31 of the second embodiment differs from the actuator 1 of the first embodiment in that the above-described central angle θ of the circular arc is set at about 360°. That is, in the actuator 31, one end 31a and another end 31b are butted against each other to form an annular shape. In other words, the actuator 31 of the second embodiment is the actuator 1 of the first embodiment in which the central angle θ is set at about 360°.

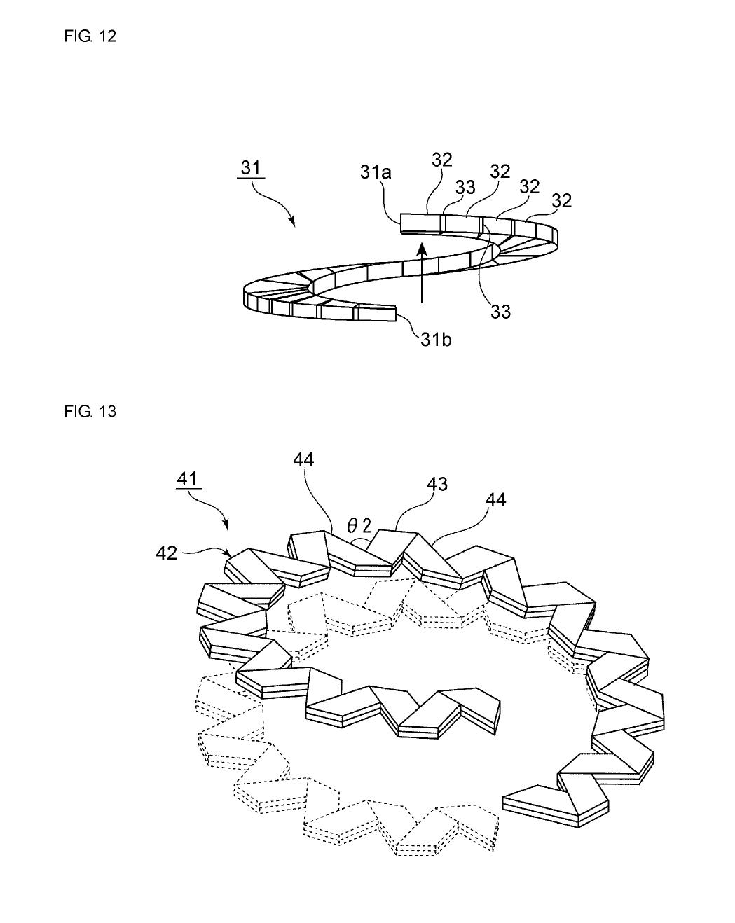

FIG. 12 is a diagram showing displacement behavior in the actuator 31.

As shown in FIG. 3, the displacement amount increases as the central angle θ increases. In the second embodiment, since the central angle θ is about 360°, it is possible to obtain a great displacement amount as shown in FIG. 12. In addition, by setting the central angle θ at about 360°, angles of generated torsion of elastic plates opposed to each other with the center O as a center are cancelled with each other. As a result, the coordinates of the one end 31a and the other end 31b in a planar direction are the same, and a difference in displacement only in a direction perpendicular to the plane occurs. That is, by setting the central angle θ at about 360°, it is possible to drive the actuator 31 in linear motion.

FIG. 13 is a perspective view showing a schematic structure of an actuator 41 according to a third embodiment of the present invention. In the actuator 41, a plurality of piezoelectric actuator units 43 and piezoelectric actuator units 44 are alternately connected to each other to form a substantially annular plate-like elastic member 42. That is, the central angle 0 of the actuator 41 is set at about 360° similarly as in the case of the second embodiment. In the actuator 41, no connection member is used, and the plurality of piezoelectric actuator units 43 and 44 are directly joined to each other to form the elastic member 42.

Each piezoelectric actuator unit 43 has the same configuration as the above-described piezoelectric actuator units 12, 17, and 21. In addition, when being seen in a plan view, each piezoelectric actuator unit 43 has an isogonal trapezoid shape and has a length direction. Moreover, each piezoelectric actuator unit 44 has the same configuration as the piezoelectric actuator unit 43, and a bending direction thereof is opposite to that of the piezoelectric actuator unit 43. The piezoelectric actuator unit 43 having a length direction and the adjacent piezoelectric actuator unit 44 are joined to each other such that the base of the piezoelectric actuator unit 43 is in contact with one of the oblique sides of the piezoelectric actuator unit 44. The joining may be achieved by an appropriate method such as diffusion joining or a joining method with an adhesive.

In the present embodiment, when being seen in a plan view, the adjacent piezoelectric actuator units 43 and 44 are joined so as to form an angle of θ2. In the present embodiment as well, the elastic member 42 has a center line which extends in the length direction thereof and has a substantially circular arc shape. By causing the piezoelectric actuator units 43 to take bending behavior and simultaneously bend-driving the piezoelectric actuator units 44 in a direction opposite to that of the piezoelectric actuator units 43, the entire elastic member 42 takes torsional behavior to be greatly displaced. Thus, when one end is fixed, the elastic member 42 is displaced from a state shown by a broken line in FIG. 13 to a state shown by a solid line in FIG. 13. In particular, as compared to the second embodiment, no connection member is used, and thus it is possible to obtain an even greater displacement amount.

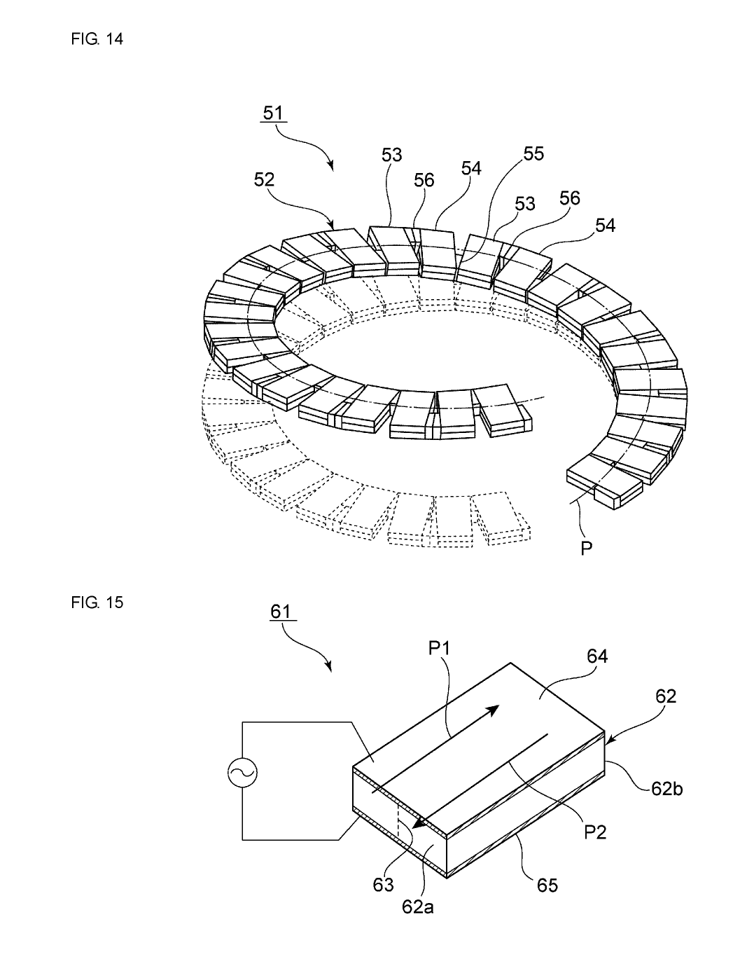

FIG. 14 is a perspective view of an actuator according to a fourth embodiment of the present invention. The actuator 51 of the present embodiment corresponds to a modification of the actuator 31 of the second embodiment.

In the actuator 51, an elastic member 52 has a center line P which passes through the center in a width direction, extends in a length direction, and has a circular arc shape, similarly as in the first to third embodiments. The elastic member 52 has a structure in which piezoelectric actuator units 53, connection members 56, piezoelectric actuator units 54, and connection members 55 are alternately connected to each other. Each piezoelectric actuator unit 53 has the same configuration as the above-described piezoelectric actuator units 12, 17, and 21, and each piezoelectric actuator unit 54 has the same configuration as the piezoelectric actuator unit 53 but a bending direction thereof is opposite to that of the piezoelectric actuator unit 53. Each connection member 55 is substantially the same as the connection member 33 of the second embodiment.

Each connection member 55 extends from the inner peripheral surface of the elastic member 52 toward the radially outer side but does not reach the outer peripheral surface of the elastic member 52. That is, each connection member 55 is located inward of the circular arc-shaped center line P. On the other hand, each connection member 56 connects the piezoelectric actuator units 53 and 54 at the outer peripheral surface side of the elastic member 52. The connection members 55 and the connection members 56 are alternately located in the circumferential direction.

In the actuator 51, the connection members 55 and the connection members 56 are alternately disposed at the outer peripheral side or the inner peripheral side in the direction in which the above-described circular arc-shaped center line extends. A plurality of the piezoelectric actuator units 53 and 54 are connected to each other via the connection members 55 and 56 such that, when the plate-like elastic member 52 is seen in a plan view, the elastic member 52 has a meander shape.

Therefore, when the elastic member 52 is deformed by bend-driving the piezoelectric actuator units 53 and 54, if one end of the elastic member 52 is fixed, the other end of the elastic member 52 is displaced greatly from a state shown by a broken line to a state shown by a solid line.

In the present embodiment as well, the above-described central angle formed by connecting the piezoelectric actuator units 53 and 54 in the elastic member 52 is set at about 360°. In the present embodiment as well, the central angle may be an angle smaller than 360°.

In the above-described first to fourth embodiments, each elastic plate is not limited to the actuator element 11 shown in FIG. 5, and may be composed of various piezoelectric actuator elements or actuator elements other than piezoelectric actuator elements. Modifications of such actuator elements will be described with reference to FIGS. 15 to 17.

FIG. 15 is a perspective view showing a first modification of the piezoelectric actuator element used in the actuator of the present invention.

A piezoelectric actuator element 61 includes a piezoelectric ceramic plate 62. The piezoelectric ceramic plate 62 has a rectangular plate shape. The piezoelectric ceramic plate 62 has a first end surface 62a and a second end surface 62b. The piezoelectric ceramic plate 62 is polarized in a direction connecting the first end surface 62a and the second end surface 62b.

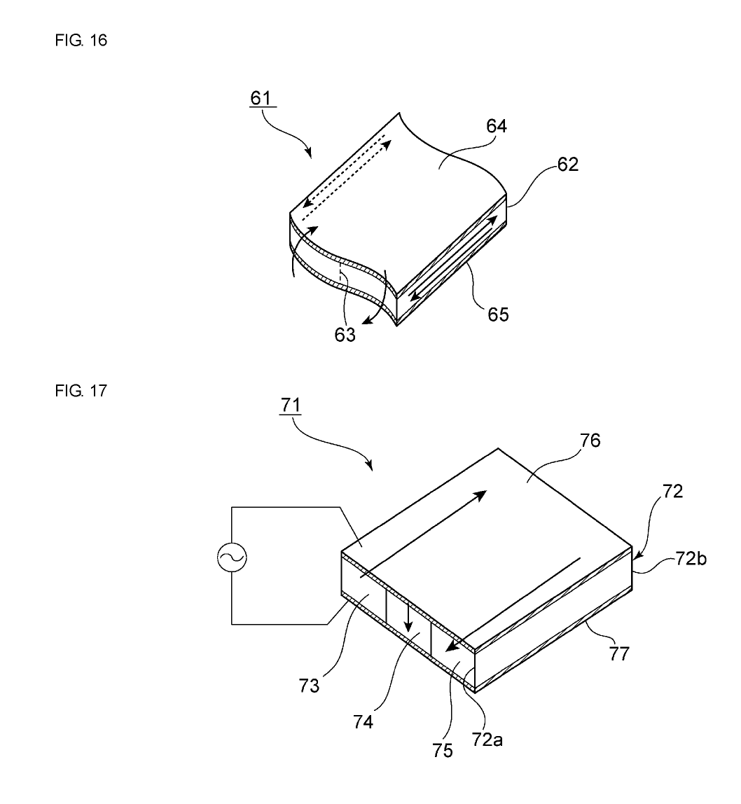

In the piezoelectric ceramic plate 62, a polarization direction arrow P1 at one side of a broken line 63 and a polarization direction arrow P2 at the other side of the broken line 63 are opposite to each other. An electrode 64 is formed on the upper surface of the piezoelectric ceramic plate 62, and an electrode 65 is formed on the lower surface of the piezoelectric ceramic plate 62. When a DC voltage is applied between the electrodes 64 and 65, the one side and the other side of the broken line 63 are displaced in a thickness sliding mode in opposite directions as shown in FIG. 16. Thus, the entire piezoelectric actuator element 61 is displaced in torsional behavior.

FIG. 17 is a perspective view showing a second modification of the piezoelectric actuator element used in the actuator of the present invention. In a piezoelectric actuator element 71, a piezoelectric ceramic plate 72 is used. The piezoelectric ceramic plate 72 has first to third regions 73 to 75 connecting a first end surface 72a and a second end surface 72b. The first to third regions 73 to 75 each connect the first end surface 72a and the second end surface 72b.

The second region 74 is located at the center and is polarized in a thickness direction as shown by an arrow in the drawing. On the other hand, the first region 73 and the third region 75 are polarized in opposite directions in a direction connecting the first and second end surfaces 72a and 72b. An electrode 76 is formed on the upper surface of the piezoelectric ceramic plate 72, and an electrode 77 is formed on the lower surface of the piezoelectric ceramic plate 72. When a DC voltage is applied between the electrodes 76 and 77, the first region 73 and the third region 75 are displaced in opposite directions in a thickness sliding mode. In addition, the second region 74 at the center is displaced in a bending mode. Therefore, the entire piezoelectric ceramic plate 72 is displaced in torsional behavior.

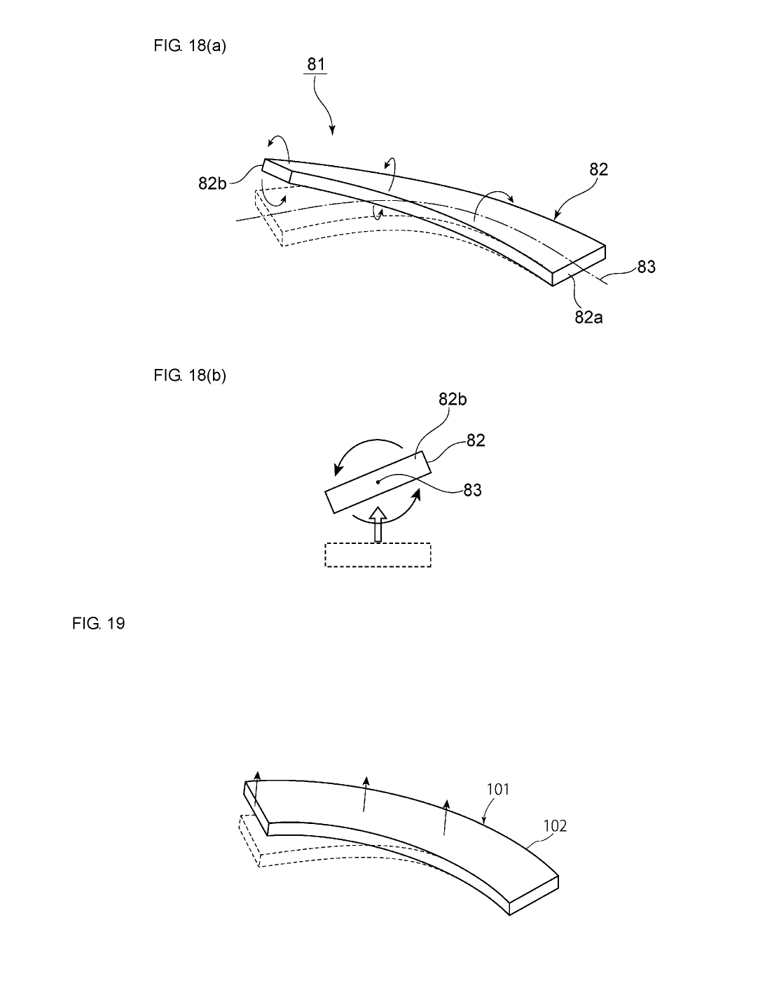

Like the piezoelectric actuator elements 61 and 71, an actuator element may be configured by using displacement utilizing a thickness sliding mode. As is obvious from each embodiment described above, by connecting a plurality of elastic plates each of which deforms in torsional behavior, an actuator may be configured to be displaced in torsional behavior in which when one end side is fixed, the other end side is greatly displaced. In this case, an elastic member may be configured by connecting a plurality of elastic plates directly or indirectly to each other as described above, a single elastic plate may be deformed in torsional behavior as described above, as in a fifth embodiment shown in FIGS. 18(a) and 18(b). As shown in FIG. 18(a), an actuator 81 includes an elastic plate 82. The elastic plate 82 has a length direction and a width direction. A center line 83 which passes through the center in the width direction and extends in the length direction of the elastic plate 82 has a circular arc shape similarly as in the actuators of the first to third embodiments. The elastic plate 82 deforms in torsional behavior with the circular arc-shaped center line 83 as a torsional central axis. That is, when the elastic plate 82 is fixed at one end 82a thereof and is deformed in torsional behavior, the elastic plate 82 is displaced from a state shown by a broken line to a state shown by a solid line. FIG. 18(b) is an end view showing a displacement state as seen from another end portion 82b side.

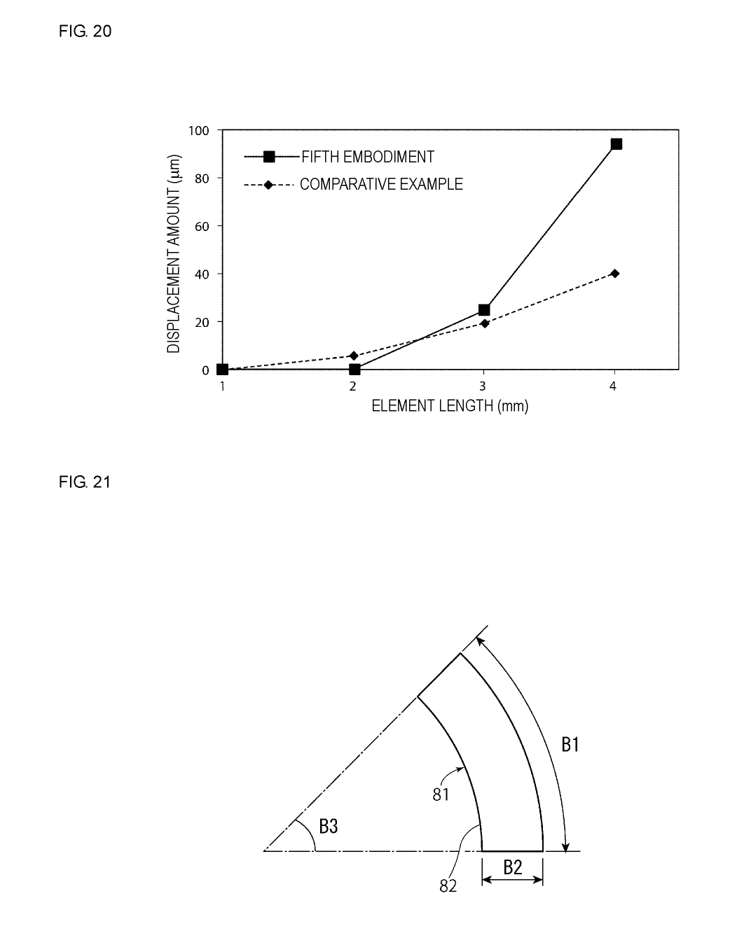

When a plurality of elastic plates are not joined and the single elastic plate 82 is deformed in torsional behavior as presented above, it is possible to obtain a great displacement amount similarly as in the above-described first to third embodiments. This is because, similarly as in the case where a plurality of elastic plates are joined to each other, displacements in torsional behavior accumulate in the direction in which the above center line 83 extends, so that a displacement enlargement ratio increases. This will be described with reference to FIG. 20.

For comparison, a comparative example shown in FIG. 19 is prepared. An elastic plate 102 forming an actuator 101 of the comparative example has a center line having a circular arc shape, similarly to the elastic plate 82. The structure of the elastic plate 102 is, for example, a unimorph structure which is substantially the same as the above-described piezoelectric actuator unit 12, and the entirety thereof is bend-driven. In the elastic plate 102, when one end side is fixed, the other end is displaced from a state shown by a broken line to a state shown by a solid line. That is, the elastic plate 102 is displaced in a bending mode. The actuator 101 which is displaced in such a bending mode is taken as the comparative example.

FIG. 20 shows a relationship between the length of an outer lateral side and a displacement amount in each of the above-described actuator 81 and the actuator 101 of the comparative example. In FIG. 20, a solid line indicates the results of the actuator 81 of the above-described embodiment, and a broken line indicates the results of the above-described comparative example.

The results shown in FIG. 20 are results obtained when the central angle B3 of the elastic member is 60°, the dimension B2 in the width direction is 1 mm, the thickness is 0.2 mm, and the length B1 of the outer peripheral lateral surface of the element is changed, as shown in FIG. 21.

As is obvious from FIG. 20, as compared to the comparative example, according to the present embodiment, it appears that it is possible to drastically increase the displacement amount by increasing the length of the element.

As is obvious from the simulation results of the actuator 81, it appears that in the present invention, it is possible to drastically increase the displacement amount by deforming, in torsional behavior, the elastic member having a center line which extends in the length direction and has a circular arc shape.

Therefore, there is no limitation to the above-described first to third embodiments, and the single elastic plate may be deformed in torsional behavior. In this case, it is understood that it is possible to reduce the number of components and further increase the displacement amount.

### REFERENCE SIGNS LIST

1, 31, 41, 51 actuator

2 elastic member

2A first lateral surface

2B second lateral surface

3 to 5 elastic plate

6, 7 connection member

8 center line

11 actuator element

12, 13, 17, 21, 43, 44, 53, 54 piezoelectric actuator unit

14, 18 elastic plate

15, 19, 20 piezoelectric element

15a, 19a, 20a, 62, 72, piezoelectric ceramic plate

15b, 15c, 19b, 19c, 20b, 20c electrode

16 connection member

31a one end

31b another end

32, 42, 52 elastic plate

33, 55, 56 connection member

61, 71, 81 piezoelectric actuator element

62a, 72a, 82a first end surface

62b, 72b, 82b second end surface

63 broken line

64, 65 electrode

73 to 75 first to regions

76, 77 electrode

83 center line

1. An actuator comprising:
an elastic member having a first principal surface and a second principal surface opposite to the first principal surface, wherein
the elastic member extends along a circular arc-shaped center line, when seen from the first principal surface side in a plan view, and the elastic member is constructed to be torsionally displaced relative to the circular arc-shaped center line as a central axis.

2. The actuator according to claim 1, wherein the elastic member includes a plurality of elastic plates connected to each other and disposed so as to extend along a direction of the circular arc-shaped center line.

3. The actuator according to claim 2, wherein adjacent elastic plates of the plurality of elastic plates are connected to each other via a connection member.

4. The actuator according to claim 2, wherein the plurality of elastic plates are connected directly to each other.

5. The actuator according to claim 1, wherein the circular arc-shaped center line has a central angle of 360°.

6. The actuator according to claim 1, wherein the elastic plate has a length direction, and the adjacent elastic plates are connected to each other so as to form a certain angle when being seen in a plan view.

7. The actuator according to claim 3, wherein the connection members are alternately disposed at an outer peripheral side and an inner peripheral side of the actuator relative to the circular arc-shaped center line.

8. The actuator according to claim 1, wherein the elastic plate includes a piezoelectric element having a piezoelectric plate and an electrode on the piezoelectric plate.

9. The actuator according to claim 7, wherein the elastic plate includes a plurality of piezoelectric elements configured to vibrate in a bending mode, and the plurality of piezoelectric elements are connected to each other so as to form a meander shape when seen in the plan view.

10. The actuator according to claim 3, wherein surfaces of the plurality of elastic plates are flush with surfaces of the connection members.

11. The actuator according to claim 3, wherein the connection member is in the form of an isosceles triangle.

12. The actuator according to claim 1, wherein the circular arc-shaped center line has a central angle equal to or greater than 50°.

13. The actuator according to claim 2, wherein adjacent elastic plates of the plurality of elastic plates are polarized in opposite directions.

14. The actuator according to claim 1, wherein the elastic plate includes a piezoelectric element having a bimorph structure.

15. The actuator according to claim 4, wherein each of the plurality of elastic plates has an isogonal trapezoid shape.
